(19) United States
(12) Patent Application Publication
(10) Pub. No.: US 2017/0092841 A1
(43) Pub. Date: Mar. 30, 2017

(54) SUBSTRATE FOR PIEZOELECTRIC BODY FORMATION, METHOD FOR MANUFACTURING THE SAME, PIEZOELECTRIC SUBSTRATE, AND LIQUID EJECTION HEAD

(71) Applicant: CANON KABUSHIKI KAISHA, Tokyo (JP)

(72) Inventors: Minako Nakasu, Tokyo (JP); Motokazu Kobayashi, Yokohama-shi (JP); Hiroto Numazawa, Kawasaki-shi (JP); Masatoshi Watanabe, Isehara-shi (JP)

(21) Appl. No.: 15/275,935

(22) Filed: Sep. 26, 2016

(30) Foreign Application Priority Data
Sep. 29, 2015 (JP) 2015-191374
Jul. 19, 2016 (JP) 2016-141683

(51) Int. Cl. H01L 41/27; H01L 41/08; H01L 41/297; B05D 3/00; C23C 30/00; B05C 11/00; B05C 9/02; H01L 41/047; H01L 41/317

(52) U.S. Cl. CPC H01L 41/27; H01L 41/0471; H01L 41/0477; H01L 41/0815; H01L 41/297; H01L 41/317; C23C 30/005; B05C 11/00; B05C 9/02; B05D 3/007

(57) ABSTRACT

A substrate for piezoelectric body formation has a base substrate layer containing at least SiO₂ or SiN in the surface, an intermediate layer containing at least one of Ti and TiO₂ on the base substrate layer, and an electrode layer containing Pt on the intermediate layer, in which the film thickness of the electrode layer is 40 nm or more and 1000 nm or less and Ti is not detected in the surface of the electrode layer by an elemental quantitative analysis method.

### BACKGROUND

Field of the Disclosure

In order to increase the adhesiveness of a base substrate and a lower electrode of a piezoelectric element in a substrate for piezoelectric body formation, a layer configuration having a Ti intermediate layer between the layers is frequently employed (Japanese Patent Laid-Open No. 10-126204).

Description of the Related Art

In order to increase the piezoelectric characteristics of a piezoelectric element, it has been proposed to increase the (100) orientation degree of a piezoelectric thin film, particularly PZT (lead zirconate titanate). Japanese Patent Laid-Open No. 2003-298136 discloses a layer configuration having 3 to 7 nm of a Ti nucleus 100% film between a lower electrode layer and a piezoelectric thin film layer. “P. Muralt, J. Appl. Phys. 100, 051605 (2006)”, which is Non-Patent Literature 1, discloses that a PbTiO₃ layer controlling the orientation is provided between a lower electrode layer and a piezoelectric thin film layer and discloses a suggestion that a piezoelectric layer is in a state where the (100) plane orientation is predominate in a composition in which the PbO amount is abundant (TiO₂ amount is insufficient). With respect to the PbTiO₃ layer, Japanese Patent Laid-Open No. 10-126204 also discloses applying a raw material compound (precursor) of the PbTiO₃ layer as a base of PZT (lead zirconate titanate), followed by drying, applying a raw material compound of the PZT thereon, followed by drying, and finally firing the resultant substance.

Japanese Patent Laid-Open No. 2003-298136 and Non-Patent Literature 1 described above disclose that a piezoelectric thin film having a high (100) orientation degree is obtained. However, in Japanese Patent Laid-Open No. 2003-298136, a lower electrode having at least an Ir layer is formed on a ZrO₂ film, and then a Ti nucleus 100% film is formed thereon, which is different from the layer configuration provided by the present disclosure.

In the formation of the PbTiO₃ layer as in Japanese Patent Laid-Open No. 10-126204 and Non-Patent Literature 1, it may be possible to disregard the configuration under a base electrode layer. However, the present inventors have found that, when the PbTiO₃ layer is formed, particularly in the case where a piezoelectric thin film is formed on a PbTiO₃ precursor as in Japanese Patent Laid-Open No. 10-126204, the (100) orientation degree of the piezoelectric thin film is not sufficiently improved in some cases even in the case of the composition in which the PbO amount is abundant as suggested in Non-Patent Literature 1.

### SUMMARY

The present disclosure has been made in view of the above-described problems. More specifically, in one embodiment, the present disclosure provides a substrate for piezoelectric body formation capable of providing a piezoelectric element in which the orientation degree of the (100) plane of a piezoelectric thin film is high, i.e., the piezoelectric characteristics are high, and a method for manufacturing the same. In another embodiment, the present disclosure also provides a piezoelectric substrate employing the substrate for piezoelectric body formation and a liquid ejection head having a piezoelectric element containing the piezoelectric substrate.

(1) A substrate for piezoelectric body formation has a base substrate layer containing at least SiO₂ or SiN in the surface, an intermediate layer containing at least one of Ti and TiO₂ on the base substrate layer, and an electrode layer containing Pt on the intermediate layer, in which the film thickness of the electrode layer is 40 nm or more and 1000 nm or less and Ti is not detected in the surface of the electrode layer by an elemental quantitative analysis method.

(2) A substrate for piezoelectric body formation has a base substrate layer containing at least SiO₂ or SiN in the surface, an intermediate layer containing at least one of Ti and TiO₂ on the base substrate layer, an electrode layer containing Pt on the intermediate layer, and an orientation controlling layer on the electrode layer, in which the orientation controlling layer contains Pb, O, and Ti and the Ti among the Pb, O, and Ti elements in the surface of the orientation controlling layer is 14.88 at. % or less.

(3) In the substrate for piezoelectric body formation according to (2) above, the orientation controlling layer contains an organic material containing Pb.

(4) In the substrate for piezoelectric body formation according to (3) above, the orientation controlling layer contains an organic material containing Ti.

(5) In the substrate for piezoelectric body formation according to (1) above, the film thickness of the intermediate layer is 2 nm or more and 50 nm or less and the film thickness of the electrode layer is 40 nm or more and 1000 nm or less.

(6) A piezoelectric substrate has a substrate for piezoelectric body formation having a base substrate layer containing at least SiO₂ or SiN in the surface, an intermediate layer containing at least one of Ti and TiO₂ on the base substrate layer, and an electrode layer containing Pt on the intermediate layer, in which the film thickness of the electrode layer is 40 nm or more and 1000 nm or less and Ti is not detected in the surface of the electrode layer by an elemental quantitative analysis method, and has a piezoelectric body provided on the surface of the substrate for piezoelectric body formation.

(7) In the piezoelectric substrate according to (6) above, the piezoelectric body is PZT (lead zirconate titanate).

(8) A liquid ejection head has a substrate for piezoelectric body formation having a piezoelectric substrate having a base substrate layer containing at least SiO₂ or SiN in the surface, an intermediate layer containing at least one of Ti and TiO₂ on the base substrate layer, and an electrode layer containing Pt on the intermediate layer, in which the film thickness of the electrode layer is 40 nm or more and 1000 nm or less and Ti is not detected in the surface of the electrode layer by an elemental quantitative analysis method, and has a piezoelectric body provided on a surface of the substrate for piezoelectric body formation.

(9) A method for manufacturing a substrate for piezoelectric body formation includes a step of forming an intermediate layer containing at least one of Ti and TiO₂ on a base substrate layer containing at least SiO₂ or SiN in the surface, a step of forming an electrode layer containing Pt on the intermediate layer, and a step of forming an orientation controlling layer containing Pb, O, and Ti on the surface of an electrode, in which the temperature T (° C.) applied to the substrate for piezoelectric body formation in the step of forming the orientation controlling layer and a time t (minutes) satisfy Expression (1) shown below,

$$T < \frac{164}{{t}^{0.03}} + 50 \\ ( 50 \leq T \leq 450 , 0 < t < 30 ) . \qquad ( 1 )$$

(10) In the manufacturing method according to (9) above, the film thickness of the intermediate layer is 2 nm or more and 50 nm or less and the film thickness of the electrode layer is 40 nm or more and 1000 nm or less.

(11) In the manufacturing method according to (9) above, the step of forming the orientation controlling layer includes applying a coating liquid containing an organometallic oxide containing Pb and Ti and an organic solvent onto the electrode to form a coating layer, and then drying the coating layer, and the drying temperature and a drying time in the drying step are a temperature T and a time t satisfying Expression (1) above.

(12) A method for manufacturing a piezoelectric substrate includes a step of applying a coating liquid containing a piezoelectric precursor and an organic solvent onto a surface of the substrate for piezoelectric body formation according to (1) above, and then drying the coating liquid to form a coating layer, drying the coating layer to form a dry coating layer, and firing the dry coating layer to form a piezoelectric thin film.

(13) In the manufacturing method according to (12) above, the piezoelectric precursor is a thermally decomposable composite organometallic oxide prepared from an organometallic compound containing Pb, an organometallic compound containing Zr, and an organometallic compound containing Ti.

Further features of the present disclosure will become apparent from the following description of exemplary embodiments with reference to the attached drawings.

### BRIEF DESCRIPTION OF THE DRAWINGS

FIG. 1 is a vertical cross-sectional schematic view illustrating a piezoelectric thin film according to one embodiment of the present disclosure.

FIG. 2 is a vertical cross-sectional schematic view illustrating a piezoelectric thin film according to one embodiment of the present disclosure.

FIG. 3 is a schematic perspective view illustrating a liquid ejection head according to one embodiment of the present disclosure.

FIG. 4 is a schematic perspective cross-sectional view illustrating a liquid ejection head according to one embodiment of the present disclosure.

FIG. 5 is a schematic cross-sectional view illustrating a liquid ejection head according to one embodiment of the present disclosure.

FIG. 6 is a view showing the X-ray diffraction pattern at a position (5) of a substrate in Example 1.

FIG. 7 is a schematic view showing X-ray diffraction measurement portions on substrates in Examples and Comparative Examples.

FIG. 8A is a view showing the XPS spectrum of all the bond energy regions on a Pt electrode surface of a substrate for piezoelectric body formation of Example 1, and FIG. 8B is an enlarged view illustrating the Ti2p orbital region of the spectrum.

FIG. 9 is a view showing the XPS spectrum of the Ti2p orbital region on a Pt electrode surface of a substrate for piezoelectric body formation in Comparative Example 1.

FIG. 10 is a view showing the (100) plane orientation degree of a PZT piezoelectric thin film stacked on an orientation controlling layer of a substrate for piezoelectric body formation in relation to the Ti amount ratio on the surface of the orientation controlling layer of the substrate for piezoelectric body formation.

### DESCRIPTION OF THE EMBODIMENTS

Hereinafter, embodiments of the present disclosure are described but the present disclosure is not limited to the following embodiments.

Herein is described the mechanism whereby, when the orientation degree of the (100) plane of a piezoelectric thin film is high, high piezoelectric characteristics are generated. With respect to the crystal orientation of a piezoelectric thin film formed by a sol-gel method, when the orientation ratio of the (100) plane is higher than the orientations of the other planes ((111) plane, (110) plane, and the like), the direction of a polarization moment approaches a deformation direction of a piezoelectric body. Therefore, the deformation amount becomes larger in a piezoelectric thin film in which the orientation ratio of the (100) plane is higher, and thus the piezoelectric thin film can be suitably used as an actuator of a liquid ejection head or the like.

### 1. Substrate for Piezoelectric Body Formation

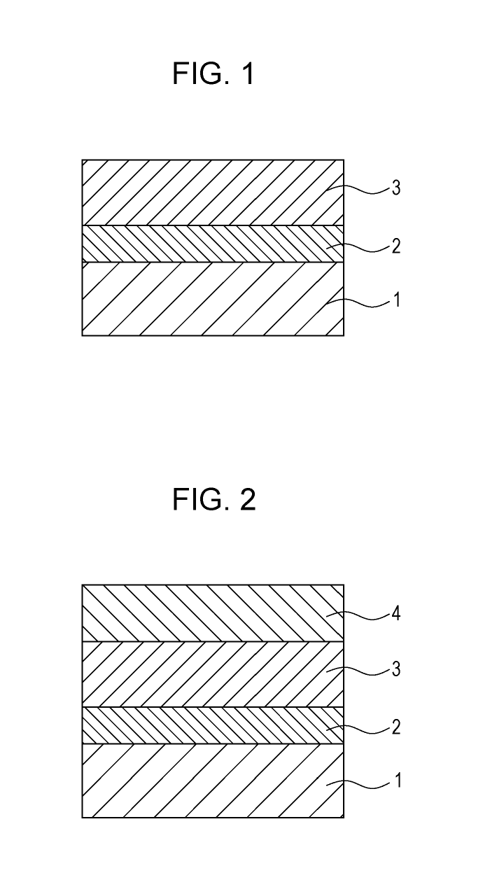

FIGS. 1 and 2 are vertical cross-sectional schematic views of a substrate for piezoelectric body formation according to one embodiment of the present disclosure. FIG. 1 illustrates a substrate for piezoelectric body formation according to a first embodiment containing a stacked structure of a base substrate layer 1, an intermediate layer 2, and an electrode layer 3. The vertical cross-sectional schematic view of FIG. 2 illustrates a substrate for piezoelectric body formation according to a second embodiment in which an orientation controlling layer 4 is stacked on the substrate for piezoelectric body formation of the configuration of FIG. 1.

The base substrate layer 1 contains at least SiO₂ or SiN in the surface and the other materials may be materials which do not deform and melt during heat treatment which may be carried out in a step of forming each layer to be formed on the base substrate layer 1. It is preferable for the base substrate layer 1 to have a smooth surface, to be free from the diffusion of elements during heat treatment, and to have sufficient mechanical strength. When manufacturing a liquid ejection head by using a piezoelectric substrate to be obtained by this embodiment, the base substrate layer 1 may function as a pressure chamber substrate for forming a pressure chamber. As materials of the base substrate layer 1, semiconductor substrates containing silicon (Si) and the like and metal substrates containing tungsten (W), heat-resistant stainless steel (SUS), and the like can be preferably used for such a purpose, for example, but ceramic substrates containing zirconia, alumina, silica, and the like may also be used. Two or more kinds of the substrate materials may be combined or may be stacked to be used as a multilayer structure. SiO₂ or SiN is formed on the surface of the materials to be used as the base substrate layer 1. For example, a Si substrate can be oxidized or nitrided to be changed to a layer in which the surface contains SiO₂ or SiN.

The intermediate layer 2 is a layer to be inserted in order to improve the adhesiveness between the base substrate layer 1 and the electrode layer 3. Therefore, the intermediate layer 2 contains at least one of Ti and TiO₂ as a material. A Ti layer and a TiO₂ layer can be stacked. The intermediate layer 2 preferably has a layer thickness of 2 nm or more and 50 nm or less. This is because, when the layer thickness of the intermediate layer 2 is 2 nm or more, sufficient layer thickness for demonstrating adhesiveness can be secured, and, when the layer thickness of the intermediate layer 2 is 50 nm or less, wasteful consumption of materials can be suppressed.

Materials of the electrode layer 3 may be materials which are usually used for a piezoelectric element containing Pt and may contain a Pt metal film and an oxide film containing Pt, metals, such as Ti, Ta, Ir, Sr, In, Sn, Au, Al, Fe, Cr, and Ni, and oxides thereof. The electrode layer 3 may contain one layer or may contain a stacked structure of two or more layers thereof. These metals and oxides may be formed by being applied onto a substrate by a sol-gel method or the like, and then fired or may be formed by sputtering, vapor-deposition, or the like. Alternatively, these metals and oxides may be patterned into a desired shape for use. The electrode layer 3 preferably has a layer thickness of 40 nm or more and 1000 nm or less. In the first embodiment, a sputtering method having a history of relatively less heat is suitable.

Several layers of atoms of the sputtered surface are disrupted by ions, which causes irradiation ions to remain and formation of an amorphous layer. Therefore, in order to remove and stabilize the remaining irradiation ions and the amorphous layer, heat treatment is performed after the sputtering in some cases. The heat treatment may be performed within a sputtering device or may be performed after removing a sputtering substance from a sputtering device.

When a piezoelectric thin film was formed on the substrate for piezoelectric body formation of such a layer configuration, a phenomenon was observed in which the orientation degree of the (100) plane of the piezoelectric thin film varied depending on heat treatment conditions. When the top of the substrate for piezoelectric body formation before the piezoelectric thin film is formed, i.e., the surface state of the electrode layer 3, was examined for the cause thereof, it was found that the orientation degree decreased when the presence of Ti was confirmed on the electrode surface and that a high orientation degree was obtained when the presence of Ti was not confirmed. A detailed structure of Ti of a substrate for piezoelectric body formation in which the (100) plane orientation degree of a piezoelectric thin film becomes high has remained unexplained until now.

Therefore, the substrate for piezoelectric body formation according to the first embodiment of the present disclosure has the base substrate layer containing at least SiO₂ or SiN in the surface, the intermediate layer containing at least one of Ti and TiO₂ on the base substrate layer, and the electrode layer containing Pt on the intermediate layer, in which Ti is not detected in the surface of the electrode layer by an elemental quantitative analysis method.

In order to suppress Ti migration from the Ti layer, passivation of the Ti layer surface is known. However, slight Ti migration occurs depending on the temperature and the time of the heat treatment after Pt sputtering. Therefore, the condition of suppressing the Ti migration by controlling the temperature and the time of the heat treatment in or after the electrode layer formation is selected in this embodiment. Such selection of the heat treatment condition can be experimentally performed. For example, the temperature of the heat treatment after sputtering in the case of forming the electrode layer by a sputtering method is preferably 280° C. or less. In order to realize the purpose of the heat treatment after sputtering, such as the removal and crystallization of remaining irradiation ions, the temperature is preferably 100° C. or higher and more preferably 150° C. or higher. The heat treatment time varies depending on the temperature conditions and is preferably 5 minutes or less, and the purpose of the heat treatment after sputtering can be realized in as little as about 1 minute.

The orientation controlling layer 4 is a layer controlling the orientation of a piezoelectric thin film layer to be stacked thereon and contains Pb, O, and Ti as the constituent atoms. Materials of the orientation controlling layer 4 are not particularly limited, and organometallic oxides containing at least Pb and/or Ti are preferably contained. In particular, a composite organometallic oxide of Pb and Ti is more preferable. The orientation controlling layer 4 also realizes an effect of preventing Pb from diffusing into a lower portion due to a temperature load in the film formation when lead zirconate titanate (PZT) is stacked as a piezoelectric thin film thereon. Furthermore, the orientation controlling layer 4 also has an effect of preventing the Ti of the intermediate layer provided below from diffusing into the piezoelectric thin film layer provided in an upper portion due to a temperature load.

As methods for manufacturing the orientation controlling layer 4, a metal organic chemical vapor deposition (MOCVD) method, a sol-gel method, and the like can be mentioned. Among the above, the sol-gel method is preferable in the respect that the orientation controlling layer can be formed at the lowest cost and in the simplest manner. In the sol-gel method, a coating liquid containing hydrolytic compounds of constituent metals serving as raw materials, partial hydrolytic compounds thereof, or partial polycondensation compounds (orientation controlling layer material) thereof is prepared first. The prepared coating liquid is applied onto a substrate, and the coating liquid is dried for the formation.

As raw materials for generating the orientation controlling layer, organometallic compounds can be mentioned. For example, alkoxides of lead or titanium, organic acid salts, and metal complexes, such as β-diketone complex, are typical examples. For the metal complexes, various other complexes, such as an amine complex, can be used. As β-diketone for forming the β-diketone complex, acetylacetone (=2,4-pentanedione), heptafluorobutanoylpivaloylmethane (=1-(heptafluoropropyl)-4,4-dimethyl-1,3-pentanedione), dipivaloylmethane (=2,2,6,6-tetramethyl-3,5-heptanedione), trifluoroacetylacetone, benzoylacetone, and the like can be mentioned.

As the lead compound, organic acid salts, such as lead acetate, and organometallic alkoxides, such as diisopropoxy lead, can be mentioned. As the titanium compound, organometallic alkoxides, such as tetraethoxytitanium, tetraisopropoxytitanium, tetra-n-butoxytitanium, tetraisobutoxytitanium, tetra-tert-butoxytitanium, and dimethoxydiisopropoxytitanium, are preferable, and organic acid salts or organometallic complexes can also be used.

As the coating liquid, the raw-material organometallic compounds mentioned above are dissolved or dispersed in an appropriate organic solvent, heat treated, and then hydrolyzed to prepare a coating liquid containing a precursor compound of lead titanate as an orientation controlling layer material, e.g., a composite organometallic oxide of Pb and Ti, for example. The composite organometallic oxide contains an organic material containing Pb and an organic material containing Ti. The Pb/Ti ratio in the orientation controlling layer material is preferably 1/1 or more and 1.8/1 or less and more preferably 1.2/1 or more and 1.5/1 or less.

The organic solvent for use in the preparation of the coating liquid is selected appropriately from various known kinds of solvents in consideration of dispersibility and coatability. As the organic solvent for use in the preparation of the coating liquid, alcohol-based solvents, such as methanol, ethanol, n-butanol, n-propanol, and isopropanol, ether-based solvents, such as tetrahydrofuran and 1,4-dioxane, cellosolve-based solvents, such as methyl cellosolve and ethyl cellosolve, amide-based solvents, such as N,N-dimethyl formamide, N,N-dimethyl acetamide, and N-methyl pyrrolidone, and nitrile-based solvents, such as acetonitrile, can be mentioned. Among the above, the alcohol-based solvents are preferably used.

The amount of the organic solvent in the coating liquid is not particularly limited. It is preferable to adjust the amount of the organic solvent so that the metal solid content concentration is 15% by mass or more and 30% by mass or less.

As coating methods of the coating liquid, known coating methods, such as spin coating, dip coating, bar coating, and spray coating, can be used. When applying the coating liquid onto the substrate, the surface of the substrate to which the coating liquid is applied is preferably disposed in a horizontal direction (direction orthogonal to the vertical direction). Thus, a coating layer having uniform film thickness and uniform distribution of the orientation controlling layer material can be obtained. The coating liquid may be applied only once or may be applied two or more times.

In the drying step after the formation step of the coating layer, the organic solvent is evaporated from the coating layer in a windless environment to obtain an orientation controlling layer. This step may be performed at a drying temperature suitable for the organic solvent to be used and is performed preferably at a temperature of 50° C. or higher and more preferably at a temperature of 100° C. or higher. The drying temperature is preferably 450° C. or less and is more preferably 300° C. or less. The drying time is preferably less than 30 minutes. Particularly in this embodiment, the drying treatment is carried out under the conditions satisfying Expression (1) shown below. This step can be performed by placing the substrate in or on heat sources, such as a drying device, a hot plate, a tubular furnace, and an electric furnace, or by bringing the substrate into direct contact with heat sources, such as a drying device, a hot plate, a tubular furnace, and an electric furnace. Among the above, a hot plate heating the substrate from the back surface of the substrate is preferable from the viewpoint of heating temperature uniformity.

The formation step of the orientation controlling layer (dry coating layer) is performed so that the surface (coated surface) which is coated with the coating liquid of the substrate is in a windless environment. Specifically, an inlet port through which warm air or hot air is supplied or an outlet port through which air is exhausted is not provided in the coated surface. When providing the inlet port and the outlet port, the generation of the flow of the evaporated organic solvent or hot air on the substrate is prevented. Thus, the flow velocity of gas at a position at a height of 20 cm from the surface which is coated with the coating liquid of the substrate is set to 0.05 m/s or less.

The film thickness of the orientation controlling layer 4 after being dried as described above is preferably 10 nm or more and 100 nm or less. When the film thickness is 10 nm or more, the effects of controlling the orientation and suppressing diffusion are sufficiently realized. When the film thickness is 100 nm or less, the characteristics of the piezoelectric thin film are not adversely affected.

According to an examination of the present inventors, the present inventors have found that the surface state of the orientation controlling layer varies depending on the drying conditions for forming the orientation controlling layer, and, even when raw materials of the same composition ratio are used, the orientation degree of the (100) plane of the piezoelectric thin film to be formed thereon varies. The present inventors have found that, particularly when the Ti among the Pb, O, and Ti elements in the surface of the orientation controlling layer is 14.88 at. % or less, a high orientation degree of the (100) plane of the piezoelectric thin film is obtained. The Ti element ratio of the surface of the orientation controlling layer is more preferably 14.8 at. % or less.

Therefore, the substrate for piezoelectric body formation according to another embodiment of the present disclosure has the base substrate layer containing at least SiO₂ or SiN in the surface, the intermediate layer containing at least one of Ti and TiO₂ on the base substrate layer, the electrode layer containing Pt on the intermediate layer, and the orientation controlling layer on the electrode layer, in which the orientation controlling layer contains Pb, O, and Ti and the Ti among the Pb, O, and Ti elements in the surface of the orientation controlling layer is 14.88 at. % or less.

The method for manufacturing the substrate for piezoelectric body formation according to the second embodiment at least includes the step of forming an intermediate layer containing at least one of Ti and TiO₂ on a base substrate layer containing at least SiO₂ or SiN in the surface, the step of forming an electrode layer containing Pt on the intermediate layer, and the step of forming an orientation controlling layer containing Pb and Ti on the surface of an electrode, in which the temperature T (° C.) applied to the substrate for piezoelectric body in the step of forming the orientation controlling layer and the time t (minutes) satisfy the following expression (1).

$$T < \frac{164}{{t}^{0.03}} + 50 \\ ( 50 \leq T \leq = 450 , 0 < t < 30 ) \qquad ( 1 )$$

Due to the fact that Expression (1) above is satisfied, the Ti among the Pb, O, and Ti elements in the surface of the orientation controlling layer can be set to 14.88 at. % or less.

### 2. Piezoelectric Substrate

Next, a piezoelectric substrate according to yet another embodiment of the present disclosure is described. In the piezoelectric substrate of this embodiment, a piezoelectric thin film is formed on the electrode layer 3 illustrated in FIG. 1 or on the orientation controlling layer 4 illustrated in FIG. 2. The orientation controlling layer is changed to lead titanate when firing the piezoelectric thin film to function as a part of the piezoelectric thin film. By providing an electrode (hereinafter also referred to as an upper electrode) facing the electrode layer 3 (hereinafter also referred to as a lower electrode) through the piezoelectric thin film on the piezoelectric substrate, a piezoelectric element is obtained. The piezoelectric element serves as an element converting power applied to the piezoelectric body by the piezoelectric effect to voltage or converting current to power. In the present disclosure, the piezoelectric element is preferably used as an element (actuator) converting voltage to power. The upper electrode may be formed over the entire surface of the piezoelectric thin film or may be formed on a part of the surface. The upper electrode may be integrally formed on the piezoelectric substrate or may be detachably formed. Materials of the upper electrode can be used without particular limitation insofar as the materials are electroconductive materials capable of applying voltage to the piezoelectric thin film and the same materials as the materials of the lower electrode can be used.

On the piezoelectric substrate, wiring layers to the upper and lower electrodes of the piezoelectric element may be formed and, for example, each wiring layer can be formed on the layer on which the lower electrode is formed by using the lower electrode materials. In this case, the upper electrode can be connected to the wiring layers through a through hole, an extraction electrode, and the like.

Materials of the piezoelectric thin film are not particularly limited and are preferably materials containing lead zirconate titanate (PZT). The PZT is preferably a Perovskite crystal represented by General Formula Pb_{(1.00-1.20)}(ZrₓTi₁₋ₓ)O₃ (x is 0.4 to 0.6). By setting the composition of Zr and Ti in the range mentioned above, a Perovskite crystal having high piezoelectricity can be obtained.

A slight amount of elements other than Pb, Zr, and Ti may be doped into the piezoelectric thin film. As specific examples of the elements usable as dopants when performing doping, elements, such as La, Ca, Sr, Ba, Sn, Th, Y, Sm, Ce, Bi, Sb, Nb, Ta, W, Mo, Cr, Co, Ni, Fe, Cu, Si, Ge, Sc, Mg, and Mn, can be mentioned. The addition amount is preferably 0.1% by mass to 2% by mass of Pb_{(1.00-1.20)}(ZrₓTi₁₋ₓ)O₃ (x is 0.4 to 0.6).

As methods for manufacturing the piezoelectric thin film, a sputtering method, a metal organic chemical vapor deposition (MOCVD) method, a sol-gel method, and the like can be mentioned. Among the above, the sol-gel method is preferable in the respect that the piezoelectric thin film can be formed at the lowest cost and in the simplest manner. In the sol-gel method, a coating liquid containing hydrolytic compounds of constituent metals serving as raw materials, partial hydrolytic compounds thereof, or partial polycondensation compounds (piezoelectric precursor) thereof is prepared first. Also with respect to the doping elements, compounds containing these elements may also be added in the preparation of the coating liquid. The prepared coating liquid is applied onto the substrate, and then the coating liquid is dried to form a coating layer. Thereafter, the coating layer is heated in the air, and further fired at a temperature equal to or higher than the crystallization temperature for crystallization to thereby form a piezoelectric thin film.

Examples of methods similar to the sol-gel method include a metal organic deposition (MOD) method. According to the MOD method, a coating liquid containing thermally decomposable organometallic compounds (metal complexes and metal organic acid salts), e.g., β-diketone metal complex and carboxylate salt, is applied as a piezoelectric precursor onto a substrate. Next, the method includes heating the coating liquid in the air or oxygen to cause evaporation of the solvent in the coating liquid and thermal decomposition of the organometallic compounds, and further firing the same at a temperature equal to or higher than the crystallization temperature thereof to form a piezoelectric thin film, for example.

In this specification, the sol-gel method, the MOD method, and a method includes a combination of the methods are referred to as the “sol-gel method”.

### 3. Method for Manufacturing Piezoelectric Thin Film

Next, a method for manufacturing a piezoelectric thin film of this embodiment is described below. The manufacturing method of this embodiment has a step of forming a coating layer, a step of forming a dry coating layer, and a step of heating a dry coating layer. Hereinafter, each step is described.

In this specification, the “coating layer” refers to a layer formed by a coating liquid applied onto a substrate before an organic solvent is evaporated. The “dry coating layer” refers to a coating layer after an organic solvent is evaporated.

### (1) Step of Forming Coating Layer

In the step of forming a coating layer, a coating liquid containing an organic solvent and a piezoelectric precursor is applied onto a substrate for piezoelectric thin film formation. Thus, the substrate on which the coating layer containing the organic solvent and the piezoelectric precursor is formed is prepared. As examples of the piezoelectric precursor, hydrolytic compounds of constituent metals, partial hydrolytic compounds thereof, partial polycondensation compounds thereof, thermally decomposable compounds, or raw materials of these compounds can be mentioned. As raw materials generating these compounds, organometallic compound can be mentioned. For example, alkoxides of the metals mentioned above, organic acid salts, and metal complexes, such as β-diketone complex, are typical examples. For the metal complexes, various other complexes, such as an amine complex, can be used. As β-diketone for forming the β-diketone complex, acetylacetone (=2,4-pentanedione), heptafluorobutanoylpivaloylmethane (=1-(heptafluoropropyl)-4,4-dimethyl-1,3-pentanedione), dipivaloylmethane (=2,2,6,6-tetramethyl-3,5-heptanedione), trifluoroacetylacetone, benzoylacetone, and the like can be mentioned.

As specific examples of the organometallic compound suitable as the raw material, organic acid salts, such as lead acetate, and organometallic alkoxides, such as diisopropoxy lead, can be mentioned as lead compounds. As titanium compounds, organometallic alkoxides, such as tetraethoxytitanium, tetraisopropoxytitanium, tetra-n-butoxytitanium, tetraisobutoxytitanium, tetra-tert-butoxytitanium, and dimethoxydiisopropoxytitanium, are preferable, and organic acid salts or organometallic complexes can also be used. With respect to zirconium compounds, organometallic alkoxides, organic acid salts, and organometallic complexes of zirconium can be used as is the case with the lead compounds and the titanium compounds mentioned above. The same substances mentioned above can be used for other metallic compounds but other metallic compounds are not limited thereto. The metallic compounds mentioned above may be combined for use. The organometallic compounds may be organometallic compounds obtained by compounding two or more kinds of constituent metals other than the compounds containing one kind of metal mentioned above.

As the coating liquid, the raw-material organometallic compounds mentioned above are dissolved or dispersed in an appropriate organic solvent, heat treating the resultant substance, and further hydrolyzing the same to prepare one containing a composite organometallic oxide (containing two or more kinds of constituent metals) as a piezoelectric precursor, for example.

The organic solvent for use in the preparation of the coating liquid is selected appropriately from various known solvents in consideration of dispersibility and coatability. As the organic solvent for use in the preparation of the coating liquid, alcohol-based solvents, such as methanol, ethanol, n-butanol, n-propanol, and isopropanol, ether-based solvents, such as tetrahydrofuran and 1,4-dioxane, cellosolve-based solvents, such as methyl cellosolve and ethyl cellosolve, amide-based solvents, such as, N,N-dimethyl formamide, N,N-dimethyl acetamide, and N-methyl pyrrolidone, and nitrile-based solvents, such as acetonitrile, can be mentioned. Among the above, the alcohol-based solvents are preferably used.

The amount of the organic solvent in the coating liquid is not particularly limited. It is preferable to adjust the amount of the organic solvent so that the metal solid content concentration is 15% by mass or more and 30% by mass or less. Due to the fact that the amount of the organic solvent in the coating liquid is within the range mentioned above, the layer thickness of the piezoelectric thin film is easily set to 150 nm or more and 400 nm or less.

The ratio of each organometallic compound in the coating liquid in the case of using a plurality of organometallic compound may be almost the same ratio as the composition ratio of materials of a piezoelectric thin film to be manufactured, e.g., Pb_{(1.00-1.20)}(ZrₓTi₁₋ₓ)O₃ (x is 0.4 to 0.6). When a piezoelectric thin film containing Pb_{(1.00-1.20}) (ZrₓTi₁₋ₓ)O₃ (x is 0.4 to 0.6) is formed, a lead compound generally has high volatility, and thus a loss of lead due to evaporation may occur during a heat treatment step described later. Therefore, in expectation of the loss of lead, a somewhat excessive amount of lead may be caused to be present, for example 2% by mol or more and 40% by mol or less based on the required amount of lead, in the composition ratio. The degree of the loss of lead varies depending on the type and film forming conditions of a lead compound and can be determined by an experiment.

Into the coating liquid, as a stabilizer, 1,8-diazabicyclo[5.4.0]-7-undecene (hereinafter sometimes indicated as “DBU”), 1,5-diazabicyclo[4.3.0]non-5-ene (hereinafter sometimes indicated as “DBN”), and 1,4-diazabicyclo[2.2.2]octane (hereinafter sometimes indicated as “DABCO”) can be added. Moreover, β-diketones (e.g., acetylacetone, heptafluorobutanoylpivaloylmethane, dipivaloylmethane, trifluoroacetylacetone, benzoylacetone, and the like), ketonic acids (e.g., acetoacetic acid, propionylacetic acid, benzoylacetic acid, and the like), lower alkyl esters, such as ethyl, propyl, and butyl of these ketonic acids, oxy acids (e.g., lactic acid, glycolic acid, α-oxybutyric acid, salicylic acid, and the like), lower alkyl esters of these oxy acids, oxy ketones (e.g., diacetone alcohol, acetoin, and the like), α-amino acids (e.g., glycine, alanine, and the like), alkanolamines (e.g., diethanolamine, triethanolamine, monoethanolamine), and the like which have been used heretofore as other stabilizers may be used in combination.

The amount of the stabilizer in the coating liquid is preferably 0.05 times mol or more to 5 times mol or less and more preferably 0.1 times mol or more to 1.5 times mol or less based on the total number of moles of metal atoms.

In an applying step, the coating liquid is applied onto an electrode of a substrate having the electrode on the surface. As coating methods of the coating liquid, known coating methods, such as spin coating, dip coating, bar coating, and spray coating, can be used. When applying the coating liquid onto the substrate, the surface of the substrate to which the coating liquid is applied is preferably disposed in a horizontal direction (direction orthogonal to the vertical direction). Thus, a coating layer having uniform film thickness and uniform distribution of the piezoelectric precursor can be obtained. The coating liquid may be applied only once or may be applied two or more times.

The film thickness of the piezoelectric thin film (piezoelectric thin film after manufacturing) obtained by applying the coating liquid once is not particularly limited and is preferably 150 nm or more and 400 nm or less. Due to the fact that the film thickness of the piezoelectric thin film is 150 nm or more, a piezoelectric thin film having excellent piezoelectric characteristics can be manufactured by a small number of times of application. Moreover, due to the fact that the film thickness of the piezoelectric thin film is 400 nm or less, epitaxial crystal growth in the layer thickness direction can be effectively caused to occur.

The film thickness of the piezoelectric thin film can be controlled by varying the concentration and the applying conditions of the piezoelectric precursor in the coating liquid and the conditions can be determined by an experiment. For example, a coating liquid having a solid content concentration of 20% by mass or more and 25% by mass is applied by a spin coating method at 2000 rpm, and then the coating liquid is dried and a piezoelectric precursor is heat-treated. Thus, a piezoelectric thin film having a film thickness of 200 nm or more and 330 nm or less can be formed by each application.

### (2) Step of Forming Dry Coating Layer

In a step of forming a dry coating layer after the step of forming the coating layer, the organic solvent is evaporated from the coating layer in a windless environment, and a dry coating layer containing the piezoelectric precursor is obtained. This step may be performed at a drying temperature suitable for the organic solvent to be used and is performed preferably at a temperature of 50° C. or higher and more preferably at a temperature of 100° C. or higher and 450° C. or less. This step can be performed by placing the substrate in or on heat sources, such as a drying device, a hot plate, a tubular furnace, and an electric furnace, or by bringing the substrate into direct contact with heat sources, such as a drying device, a hot plate, a tubular furnace, and an electric furnace. Among the above, a hot plate heating the substrate from the back surface of the substrate is preferable from the viewpoint of heating temperature uniformity.

The step of forming the dry coating layer is performed so that the surface (coated surface) which is coated with the coating liquid of the substrate is in a windless environment. Specifically, an inlet port through which warm air or hot air is supplied or an outlet port through which air is exhausted is not provided in the coated surface. When providing the inlet port and the outlet port, the generation of the flow of the organic solvent or hot air on the substrate is prevented. Thus, the flow velocity of gas at a position at a height of 20 cm from the surface which is coated with the coating liquid of the substrate is set to 0.05 m/s or less.

### (3) Step of Heating Dry Coating Layer

After the formation of the dry coating layer, the step of heating the dry coating layer includes heating the dry coating layer to form a piezoelectric thin film from the piezoelectric precursor contained in the dry coating layer. This step can be performed by placing a substrate in or on heat sources, such as a drying device, a hot plate, a tubular furnace, and an electric furnace, or by bringing the heat sources into direct contact with the substrate. In the step, the heating is preferably performed at 500° C. or higher and 800° C. or less. The step of heating the dry coating layer may be performed in a plurality of steps or may be performed only once. Preferably, the dry coating layer is heated by calcination, and further fired at a temperature equal to or higher than the crystallization temperature thereof for crystallization to thereby form a piezoelectric thin film.

### 4. Manufacturing Device of Piezoelectric Thin Film

A manufacturing device of the piezoelectric thin film has an application means, a drying means, and a heating means. The application means can form a coating layer by applying a coating liquid containing an organic solvent and a piezoelectric precursor onto a substrate. It is configured so that the substrate is placed on a placement portion. The drying means can obtain a dry coating layer containing a piezoelectric precursor by evaporating the organic solvent from the coating layer in a windless environment. The heating means can form a piezoelectric thin film from the piezoelectric precursor contained in the dry coating layer by heating the dry coating layer.

### 5. Orientation Evaluation Method

Next, a method for evaluating the orientation of the (100) plane of the piezoelectric thin film is described. The orientation state of the (100) plane of the piezoelectric thin film can be easily confirmed from the detection angle and the intensity of the diffraction peak in X-ray diffraction measurement by a 2θ/θ method using a CuKα ray for the wavelength, which is generally used for a crystal thin film. For example, as shown in FIG. 6, in the diffraction chart obtained from the piezoelectric thin film of this embodiment, the (100) plane has the peak intensity around 22°, the (111) plane has the peak intensity around 31°, and the (110) plane has the peak intensity around 38°. By dividing the peak intensity of the (100) plane by the sum of the intensities of the (100) plane, the (110) plane, and the (111) plane, the peak intensity ratio of the (100) plane can be determined.

Since good piezoelectricity is obtained, the intensity ratio of the (100) plane to the sum of the intensities of the (100) plane, the (110) plane, and the (111) plane is preferably 80% or more and more preferably 90% or more in each portion of the substrate. The principal surface of the substrate and the (100) plane of the piezoelectric thin film are preferably in parallel to each other.

### 6. Elemental Quantitative Analysis Method

Next, the elemental quantitative analysis method of the surface of a thin film is described. In the present disclosure, an X-ray photoelectron spectrum (XPS) analysis device of Auantera SXM manufactured by Ulvac-Phi, Inc. is used. Using software for analysis (MultiPak Version 9.3.0.3), the element amount (at. %) is calculated by using a relative sensitivity coefficient method described in Japanese Patent Laid-Open No. 7-35711.

Measurement conditions
X-ray source: Monochromatized AlKa
X-ray output: 25 W 15 kV
X-ray beam diameter: 100 μm
Photoelectron extraction angle: 45°

The elemental quantitative analysis method of the thin film surface is not limited to the XPS and analysis techniques, such as fluorescent X-ray (XRF) analysis and high frequency glow discharge optical emission spectrometry (GDOES), can be used, for example, in addition to the XPS.

In this specification, the description “Ti is not detected by an elemental quantitative analysis method” means that the Ti2p peak is not detected by XPS in a region where the bond energy is 450 eV or more and less than 470 eV, for example. The description that “the Ti among the Pb, O, and Ti elements in the surface of the orientation controlling layer is 14.88 at. % or less” means that a value obtained by dividing the Ti element amount obtained by an elemental quantitative analysis method employing XPS by the total sum of the element amounts of Pb, O, and Ti is 14.88% or less, for example. Herein, the Ti element amount in the surface of the orientation controlling layer can be calculated from the spectrum equivalent to the Ti2p orbital of XPS. The Pb element amount can be calculated from the spectrum equivalent to the Pb4f orbital. The O element amount can be calculated from the spectrum equivalent to the O1s orbital.

### 7. Liquid Ejection Head

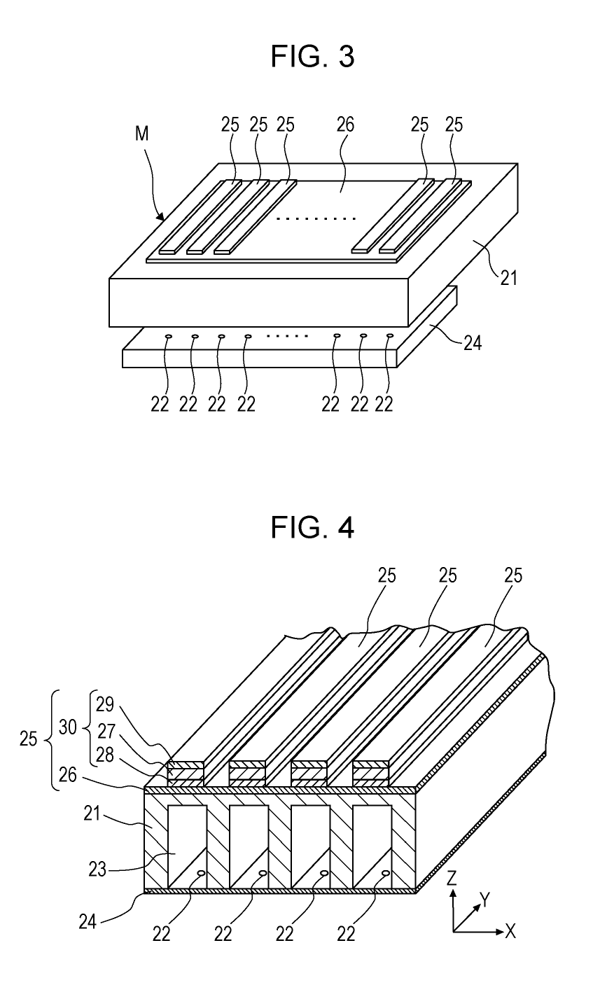

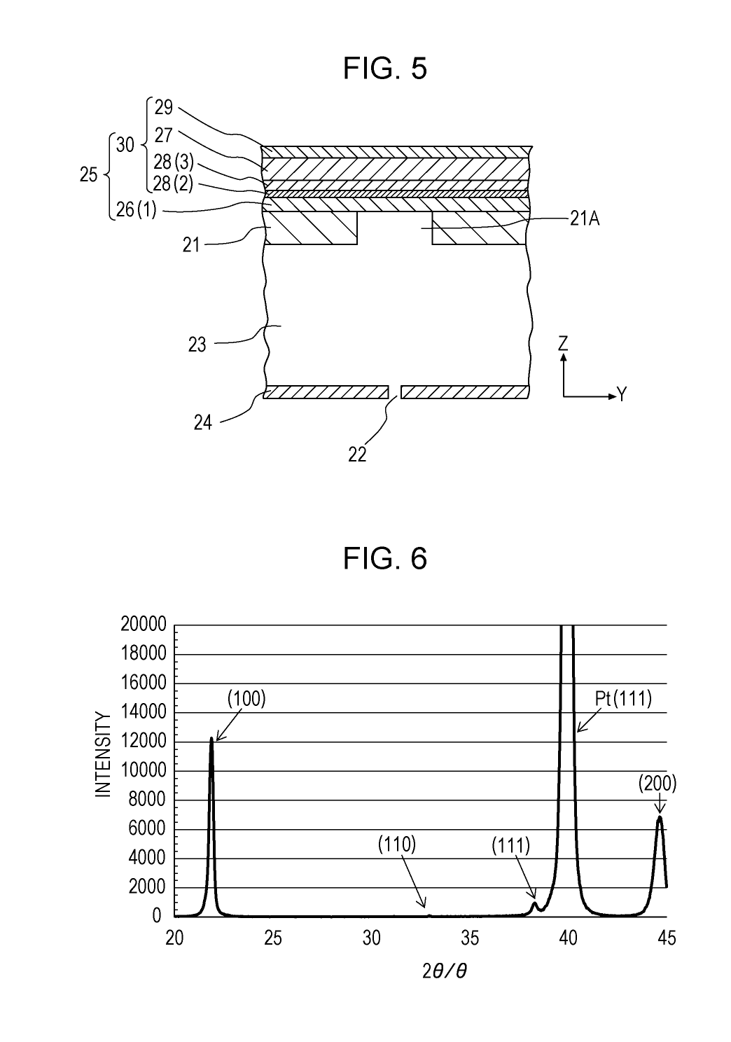

FIG. 3 to FIG. 5 illustrate a liquid ejection head according to one embodiment employing a piezoelectric substrate. A liquid ejection head M has a liquid ejection head substrate 21, a plurality of liquid ejection ports 22, a plurality of pressure chambers 23, and actuators 25 disposed corresponding to the respective pressure chambers 23. Each pressure chamber 23 is provided corresponding to each liquid ejection port 22 and communicates with each liquid ejection port 22. The actuators 25 cause ink capacity changes in the pressure chambers 23 due to the vibration thereof to eject liquid droplets of ink and the like from the liquid ejection ports 22. The liquid ejection ports 22 are formed at predetermined intervals in a nozzle plate 24. The pressure chambers 23 are formed in parallel to each other in the liquid ejection head substrate 21 so as to correspond to the respective liquid ejection ports 22. In this embodiment, the liquid ejection ports 22 are provided in the opposite surface to the surface in which pressure is generated by the actuators 25 but can also be provided on a portion other than the opposite surface to the surface in which pressure is generated by the actuators 25. Each actuator 25 contains a diaphragm 26 and a piezoelectric element 30. The piezoelectric element 30 contains a piezoelectric thin film 27 and a pair of electrodes (a lower electrode 28 and an upper electrode 29). Opening portions 21A corresponding to the respective pressure chambers 23 are formed in the upper surface of the liquid ejection head substrate 21. Each actuator 25 is disposed so as to close the opening portion 21A. FIG. 5 illustrates the configuration in which the diaphragm 26 is exposed into the opening portion 21A. However, the liquid ejection head substrate 21 may partially remain insofar as the liquid in the pressure chambers 23 can be ejected from the liquid ejection ports 22 due to vibration generated in the actuators 25. FIG. 3 illustrates the state where the nozzle plate 24 is separated from the liquid ejection head substrate 21 and rasterized for explanation. In actual, the nozzle plate 24 is joined to the liquid ejection head substrate 21 as illustrated in FIG. 4.

Materials of the diaphragm 26 are not particularly limited and semiconductors, such as Si, metals, metal oxides, glass, and the like mentioned as examples of the materials of the base substrate layer are preferable. The liquid ejection head substrate 21 and the diaphragm 26 may be formed by junction or adhesion or the diaphragm 26 may be directly formed on the liquid ejection head substrate 21. Alternatively, the lower electrode 28 and the piezoelectric thin film 30 may be directly formed on the liquid ejection head substrate 21 without providing the diaphragm 26.

In an actuator to which the present disclosure is applied, the diaphragm 26 is equivalent to the base substrate, the base substrate layer 2 containing SiO₂ or SiN is formed on the surface, and the intermediate layer 3 is formed on the base substrate layer. When the intermediate layer has electroconductivity, the intermediate layer forms a part of the lower electrodes 28. When the orientation controlling layer is formed on the lower electrode and the piezoelectric thin film is formed thereon, the orientation controlling layer is also fired in the final stage of the piezoelectric thin film formation to form a part of the piezoelectric thin film.

### EXAMPLES

Hereinafter, the present disclosure is more specifically described with reference to Examples but the present disclosure is not limited to Examples described below.

### Production of Lead Zirconate Titanate (PZT) Coating Liquid

As a coating liquid for forming a piezoelectric thin film, a PZT coating liquid in which the metal composition is represented by Pb/Zr/Ti=1.2/0.52/0.48 was prepared as follows.

1.2 mol of lead acetate hydrate is dehydrated by heating, 1.2 mol of 1,8-diazabicyclo[5.4.0]-7-undecene and 1-methoxy-2-propanol (9.0 mol) are mixed as stabilizers, and then the mixture is heated and stirred for reaction. Then, 0.52 mol of tetra-n-butoxyzirconium and 0.48 mol of tetraisopropoxytitanium were added, and further heated for reaction to compound the metallic compounds with each other. Next, water (5.0 mol) and ethanol (5.0 mol) were added, and then a hydrolysis reaction was carried out to obtain a piezoelectric precursor containing an organometallic oxide. In the process, acetic acid (3.8 mol) and acetyl acetone (0.6 mol) were added. Thereafter, a solvent having a boiling point of 100° C. or less was completely removed with a rotary evaporator, and then diethylene glycol monoethyl ether (organic solvent) was added to adjust the concentration of a metal oxide in terms of the composition formula above to 23% by mass to prepare a PZT coating liquid.

### Example 1

On the surface of a silicon substrate having a diameter of 6 inches (15 cm), a 500 nm silica (SiO₂) layer was provided as the base substrate layer 1 by thermal oxidation, and further 50 nm Ti as the intermediate layer 2 and 200 nm Pt as the electrode layer 3 were formed to form a substrate for piezoelectric body formation to be used in this example (FIG. 1). As annealing after the sputtering, heat treatment was performed by the following method.

The substrate for piezoelectric body formation was placed on a hot plate (manufactured by As One Corporation., “Shamal hot plate HHP-411”, Temperature unevenness of the plate surface of 150° C.±1° C.) heated to 150° C. for 1 minute to heat the substrate. In this process, the hot plate was placed in a windless environment (Air velocity of 0 m/s) (Measured at a position at a height of 2 cm from the substrate; Anemometer: DT-8880 manufactured by CEM was used.), and a shield plate or the like was not provided. Example 2, Comparative Examples 1 to 3

In Example 1, substrates for piezoelectric body formation were produced by the same process as that of Example 1, except changing the plate surface temperature of the hot plate and the heating time to the conditions shown in Table 1.

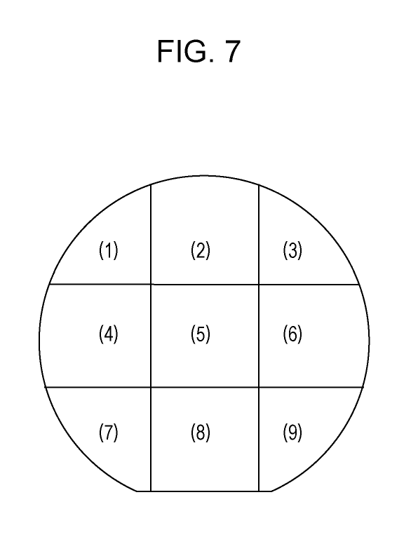

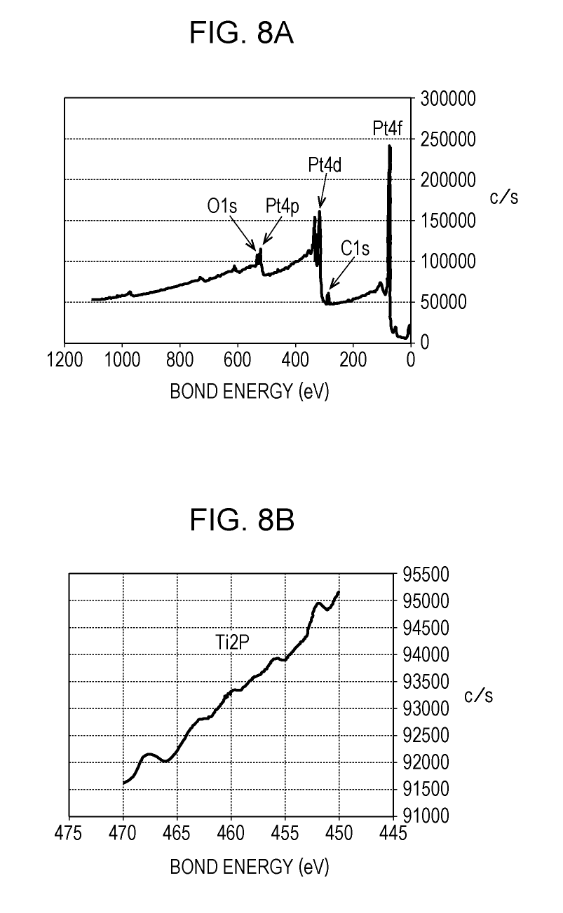

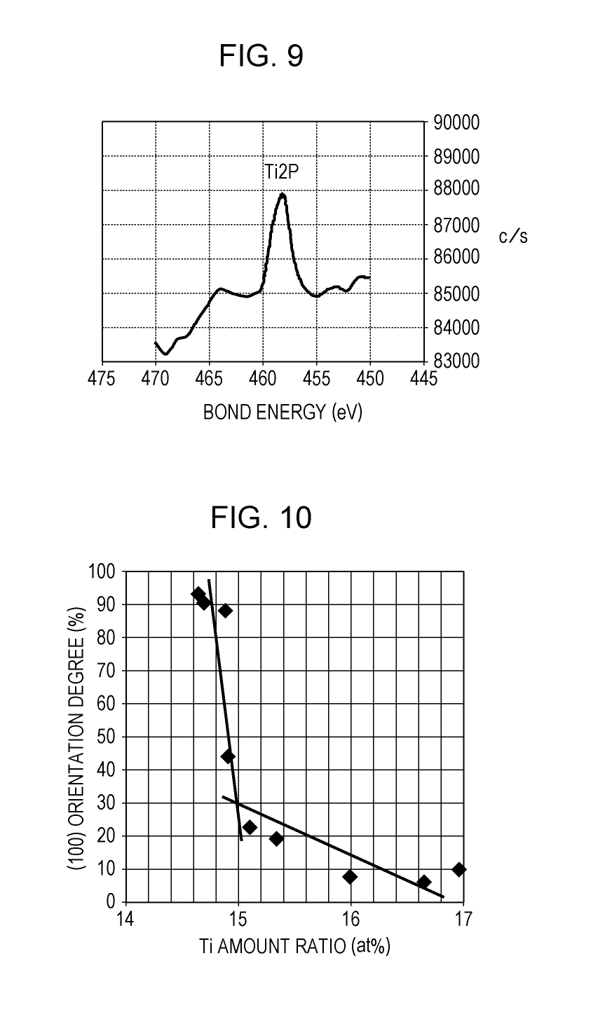

The top of the substrates for piezoelectric body formation produced in Examples 1 to 2 and Comparative Examples 1 to 3 was evaluated as follows. When each substrate for piezoelectric body formation was divided into 9 portions as illustrated in FIG. 7, and then Ti in the Pt electrode surface of each substrate for piezoelectric body formation was detected, the amount ratio was measured by XPS analysis. Herein, the Ti amount ratio can be calculated by dividing the at. % calculated from the peak equivalent to the Ti2p orbital by the sum of the at. % calculated from the peak equivalent to the Pt4f orbital and the at. % calculated from the peak equivalent to the Ti2p orbital and is an average value of values obtained by 3 times of measurement by the XPS. In FIG. 7, the measurement was performed in a portion (5) which is a portion 3 cm in radius from the center of the substrate and portions (1), (2), (3), (4), (6), (7), (8), and (9) which are portions 3 cm or more and 6 cm or less cm in radius from the center of the substrate. The results are shown in Table 1. Moreover, the XPS spectrum in all the bond energy regions of Example 1 is shown in FIG. 8A and the XPS spectrum of only the Ti2p region (from 450 nm to 470 nm) where the Ti2p peak was not detected is shown in FIG. 8B. Furthermore, the XPS spectrum in which the Ti2p peak was detected of the substrate for piezoelectric body formation produced by Comparative Example 1 is shown in FIG. 9.

Next, the PZT coating liquid prepared as described above was applied to the Pt surface of the substrate with a spin coater (4000 rpm, 15 seconds) (Process of forming coating layer). Next, a hot plate (Manufactured by As One Corporation., “Shamal hot plate HHP-411”, Temperature unevenness of the plate surface of 280° C.±1° C.) heated to 280° C. was prepared. On the hot plate, the substrate to which the PZT coating liquid was applied was placed for 5 minutes to evaporate the organic solvent in the PZT coating liquid (Process of forming dry coating layer). In this process, the hot plate was placed in a windless environment (Air velocity of 0 m/s) (Measured at a position at a height of 2 cm from the substrate; Anemometer: DT-8880 manfufactured by CEM was used.), and a shield plate or the like was not provided. The substrate for piezoelectric body formation was placed in a 650° C. electric furnace for 10 minutes to form the piezoelectric precursor into a piezoelectric thin film containing Pb_{1.2}(Zr_{0.52}Ti_{0.48})O₃. The heat treatment process for 10 minutes in the 650° C. electric furnace is equivalent to the process of heating a dry coating layer. Thereafter, the X-ray diffraction (2θ/θ method) of each piezoelectric thin film was measured with an X-ray diffraction device (manufactured by Rigaku Corporation, RINT2100). FIG. 6 shows the X-ray diffraction pattern of (5) of Example 1, and the peak observed around 40° in FIG. 6 is the peak of the (111) plane of Pt provided on the substrate.

From FIG. 6, a value obtained by dividing the peak intensity value of the (100) plane of the piezoelectric thin film by the sum of the peak intensity values of the (100) plane, the (110) plane, and the (111) plane was defined as the intensity ratio (orientation degree) of the (100) plane. The peak of the (200) plane observed around 44° is a crystal surface equivalent to the (100) plane, and therefore the intensity thereof is not included in the intensity of the (100) plane. The orientation degree in the (100) plane of each of Examples 1 and 2 and Comparative Examples 1 to 3 is shown in Table 1.

TABLE 1

| | | | | (100) plane |
|---|---|---|---|---|
| | Plate surface | Heating | Ti amount | orientation |
| | temperature (° C.) | time (minutes) | ratio (at. %) | degree (%) |
| Ex. 1 | 150 | 1 | Not | 92.6 |
| | | | detected | |
| Ex. 2 | 280 | 1 | Not | 91.9 |
| | | | detected | |
| Comp. | 400 | 1 | 2.60 | 46.8 |
| Ex. 1 | | | | |
| Comp. | 400 | 5 | 2.89 | 17.7 |
| Ex. 2 | | | | |
| Comp. | 400 | 10 | 3.12 | 11.7 |
| Ex. 3 | | | | |

As shown in Table 1, it was clarified that, when Ti was not detected in the Pt electrode, the (100) plane orientation degree as high as 90% or more is obtained. In particular, the formation of a piezoelectric thin film having a high (100) plane orientation degree was realized without the formation of a layer controlling the orientation of a piezoelectric thin film.

### Example 3

### Production of Orientation Controlling Layer Coating Liquid

A coating liquid of an orientation controlling layer having a metal composition represented by Pb/Ti=1.2/1.0 was prepared as follows.

1.2 mol of lead acetate hydrate is dehydrated by heating, 1.2 mol of 1,8-diazabicyclo[5.4.0]-7-undecene and 1-methoxy-2-propanol (9.0 mol) are mixed as stabilizers, and then the mixture is heated and stirred for reaction. Thereafter, 1.0 mol of tetraisopropoxytitanium was added, and further heated for reaction to compound the metallic compounds with each other. Next, water (5.0 mol) and ethanol (5.0 mol) were added, and then a hydrolysis reaction was carried out to obtain an orientation controlling material containing an organometallic oxide. In the process, acetic acid (3.8 mol) and acetyl acetone (0.6 mol) were added. Thereafter, a solvent having a boiling point of 100° C. or less was removed with a rotary evaporator, and then diethylene glycol monoethyl ether (organic solvent) was added to adjust the solid content concentration so that the concentration in terms of zinc titanium of the metal composition above was 1.0% by mass to prepare an orientation controlling layer coating liquid.

The orientation controlling layer coating liquid prepared as described above was applied onto the Pt surface of the substrate for piezoelectric body formation in 15 seconds with a spin coater (2000 rpm) (Process of forming coating layer). Next, a hot plate (Manufactured by As One Corporation., “Shamal hot plate HHP-411”, Temperature unevenness of the plate surface of 130° C.±1° C.) heated to 130° C. was prepared. On the hot plate, the substrate to which the coating liquid was applied was placed for 1 minute to evaporate the organic solvent in the coating liquid (Process of forming dry coating layer). In this process, the hot plate was placed in a windless environment (Air velocity of 0 m/s) (Measured at a position at a height of 2 cm from the substrate; Anemometer: DT-8880 manufactured by CEM was used.), and a shield plate or the like was not provided.

### Examples 4 to 11 and Comparative Examples 4 to 9

Substrates for piezoelectric body formation were produced by the same process as that of Example 1, except changing the drying temperature and the drying time of the process of forming a dry coating layer in Example 3 to those shown in Table 2.

The top of the substrates for piezoelectric body formation produced in Examples 3 to 11 and Comparative Examples 4 to 6 was evaluated as follows. Each substrate for piezoelectric body formation was divided into 9 portions as illustrated in FIG. 7, and then the Ti amount ratio of the surface of each orientation controlling layer was measured by using XPS. Herein, the Ti amount ratio (at. %) can be calculated by dividing the element amount calculated from the peak equivalent to the Ti2p orbital by the sum of the element amount calculated from the peak equivalent to the Pt4f locus, the element amount calculated from the peak equivalent to the Ti2p orbital, and the element amount calculated from the peak equivalent to the O1s orbital and is an average value of values obtained by 3 times of measurement by the XPS. The results are shown in Table 2.

Next, the PZT coating liquid prepared as described above was applied onto the surface of each orientation controlling layer, and then dried in the same manner as in Examples 1 and 2 and Comparative Examples 1 to 3. Then, by measuring the X-ray diffraction (2θ/θ method) of each piezoelectric thin film with an X-ray diffraction device (manufactured by Rigaku Corporation, RINT2100), the orientation degree of the (100) plane was derived (Table 2). Herein, the environment, such as windless environment and shade plate, of the hot plate, is the same as that of Examples 1 and 2 and Comparative Examples 1 to 3. FIG. 10 shows the relationship between the Ti amount ratio in terms of at. % and the (100) plane orientation degree (%) of PZT derived by the above-described technique. It was found that the (100) plane orientation degree of PZT criticality varied when the Ti amount ratio of the orientation controlling layer surface was 14.88 at. %, and the (100) plane orientation degree of PZT was high at 14.88 at. % or less.

TABLE 2

| | | | | (100) plane |
|---|---|---|---|---|
| | Drying | Drying | Ti amount | orientation |
| | temperature (° C.) | time (minutes) | ratio (at. %) | degree (%) |
| Ex. 3 | 130 | 1 | 13.87 | 97.02 |
| Ex. 4 | 130 | 5 | 14.05 | 94.89 |
| Ex. 5 | 130 | 10 | 14.43 | 92.34 |
| Ex. 6 | 150 | 1 | 14.63 | 94.53 |
| Ex. 7 | 150 | 5 | 14.67 | 91.14 |
| Ex. 8 | 150 | 10 | 14.87 | 89.08 |
| Ex. 9 | 200 | 1 | 14.64 | 93.85 |
| Ex. 10 | 200 | 5 | 14.83 | 89.86 |
| Ex. 11 | 200 | 10 | 14.70 | 88.88 |
| Comp. | 280 | 1 | 14.90 | 44.89 |
| Ex. 4 | | | | |
| Comp. | 280 | 5 | 15.08 | 23.70 |
| Ex. 5 | | | | |
| Comp. | 280 | 10 | 15.32 | 19.92 |
| Ex. 6 | | | | |
| Comp. | 400 | 1 | 15.98 | 8.56 |
| Ex. 7 | | | | |
| Comp. | 400 | 5 | 16.63 | 7.11 |
| Ex. 8 | | | | |
| Comp. | 400 | 10 | 16.94 | 10.94 |
| Ex. 9 | | | | |

### Heating Process Condition in Formation of Orientation Controlling Layer

The (100) plane orientation degree of the piezoelectric thin film varies depending on the heating process conditions (drying temperature and drying time) in forming the orientation controlling layer and the orientation degree of the (100) plane with less heat load is improved (Table 2). From FIG. 10 and Table 2, a preferable drying temperature T (° C.) and a preferable drying time t (minutes) of the orientation controlling layer can be defined by the following expression (1).

$$T < \frac{164}{{t}^{0.03}} + 50 \\ ( 50 \leq T \leq 450 , 0 < t < 30 ) \qquad ( 1 )$$

According to Expression (1), the orientation degree under each of the temperature and time conditions is calculated supposing the temperatures in increments of 10° C. and the time in increments of 1 minute from the experiment data points (T=200, 280° C., t=1, 5, and 10 minutes) of the orientation degree as the sequence of numbers with common difference. The critical point of the orientation degree shown in FIG. 10 is set to 85%, and then the boundary condition (temperature, time) points are derived. The relational expression of the temperature and the time was selected as T=A×t̂(−B)+C, and the A, B, and C coefficients were calculated and derived by least-squares fitting of the boundary condition points determined above and the relational expression.

Herein, the drying temperature and drying time conditions of the orientation controlling layers of Examples 3 to 11 showing a high (100) plane orientation degree of the piezoelectric thin film satisfy Expression (1). Comparative Examples 4 to 8 all do not satisfy Expression (1). It was confirmed that the Ti amount ratio of the surface of the orientation controlling layer can be set to 14.88 at. % or less by satisfying Expression (1).

By the use of the substrates for piezoelectric body formation of the embodiments, a piezoelectric substrate in which the (100) plane orientation ratio of a piezoelectric thin film is high, i.e., having high piezoelectric characteristics, can be provided. Moreover, by the use of the piezoelectric substrate, a liquid ejection head having excellent liquid ejection droplet performance is provided.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2015-191374 filed Sep. 29, 2015 and No. 2016-141683 filed Jul. 19, 2016, which are hereby incorporated by reference herein in their entirety.

What is claimed is:

1. A substrate for piezoelectric body formation comprising:
a base substrate layer containing at least SiO₂ or SiN in a surface;
an intermediate layer containing at least one of Ti and TiO₂ on the base substrate layer; and
an electrode layer containing Pt on the intermediate layer, wherein
a film thickness of the electrode layer is 40 nm or more and 1000 nm or less, and
Ti is not detected in a surface of the electrode layer by an elemental quantitative analysis method.

2. A substrate for piezoelectric body formation comprising:
a base substrate layer containing at least SiO₂ or SiN in a surface;
an intermediate layer containing at least one of Ti and TiO₂ on the base substrate layer;
an electrode layer containing Pt on the intermediate layer; and
an orientation controlling layer on the electrode layer, wherein
the orientation controlling layer contains Pb, O, and Ti, and
the Ti among the Pb, O, and Ti elements in a surface of the orientation controlling layer is 14.88 at. % or less.

3. The substrate for piezoelectric body formation according to claim 2, wherein
the orientation controlling layer contains an organic material containing Pb.

4. The substrate for piezoelectric body formation according to claim 3, wherein
the orientation controlling layer contains an organic material containing Ti.

5. The substrate for piezoelectric body formation according to claim 1, wherein
a film thickness of the intermediate layer is 2 nm or more and 50 nm or less, and
a film thickness of the electrode layer is 40 nm or more and 1000 nm or less.

6. A piezoelectric substrate comprising:
a substrate for piezoelectric body formation having
a base substrate layer containing at least SiO₂ or SiN in a surface,
an intermediate layer containing at least one of Ti and TiO₂ on the base substrate layer, and
an electrode layer containing Pt on the intermediate layer, wherein
a film thickness of the electrode layer is 40 nm or more and 1000 nm or less, and
Ti is not detected in a surface of the electrode layer by an elemental quantitative analysis method; and
a piezoelectric body provided on a surface of the substrate for piezoelectric body formation.

7. The piezoelectric substrate according to claim 6, wherein
the piezoelectric body is PZT (lead zirconate titanate).

8. A liquid ejection head comprising:
a substrate for piezoelectric body formation having
a base substrate layer containing at least SiO₂ or SiN in a surface,
an intermediate layer containing at least one of Ti and TiO₂ on the base substrate layer, and
an electrode layer containing Pt on the intermediate layer, wherein
a film thickness of the electrode layer is 40 nm or more and 1000 nm or less, and
Ti is not detected in a surface of the electrode layer by an elemental quantitative analysis method; and
a piezoelectric body provided on a surface of the substrate for piezoelectric body formation.

9. A method for manufacturing a substrate for piezoelectric body formation, the method comprising:
forming an intermediate layer containing at least one of Ti and TiO₂ on a base substrate layer containing at least SiO₂ or SiN in a surface;
forming an electrode layer containing Pt on the intermediate layer; and
forming an orientation controlling layer containing Pb, O, and Ti on a surface of an electrode, wherein
a temperature T (° C.) applied to the substrate for piezoelectric body formation in the formation of the orientation controlling layer and a time t (minutes) satisfy Expression (1) shown below,
$$T < \frac{164}{{t}^{0.03}} + 50 \\ ( 50 \leq T \leq 450 , 0 < t < 30 ) . \qquad ( 1 )$$

10. The manufacturing method according to claim 9, wherein
a film thickness of the intermediate layer is 2 nm or more and 50 nm or less, and
a film thickness of the electrode layer is 40 nm or more and 1000 nm or less.

11. The manufacturing method according to claim 9, wherein
the formation of the orientation controlling layer includes
applying a coating liquid containing an organometallic oxide containing Pb and Ti and an organic solvent onto the electrode to form a coating layer, and
drying the coating layer, and
a drying temperature and a drying time in the drying are a temperature T and a time t satisfying Expression (1).

12. A method for manufacturing a piezoelectric substrate, the method comprising:
applying a coating liquid containing a piezoelectric precursor and an organic solvent onto a surface of the substrate for piezoelectric body formation according to claim 1, and then drying the coating liquid to form a coating layer,
drying the coating layer to form a dry coating layer, and
firing the dry coating layer to form a piezoelectric thin film.

13. The manufacturing method according to claim 12, wherein
the piezoelectric precursor is a thermally decomposable composite organometallic oxide prepared from an organometallic compound containing Pb, an organometallic compound containing Zr, and an organometallic compound containing Ti.
